(19) United States
(12) Patent Application Publication
(10) Pub. No.: US 2009/0229134 A1
(43) Pub. Date: Sep. 17, 2009

(54) ENCODER INCLUDING ABNORMALITY DETECTING DEVICE AND CONTROL SYSTEM THEREOF

(76) Inventor: Takashi Nagase, Saitama (JP)

Correspondence Address: SUGHRUE-265550, 2100 PENNSYLVANIA AVE. NW, WASHINGTON, DC, 20037-3213, US

(21) Appl. No.: 11/996,355

(22) PCT Filed: Jun. 27, 2006
(86) PCT No.: PCT/JP2006/312812

§ 371 Date: Jan. 22, 2008

(30) Foreign Application Priority Data
Jul. 19, 2005 (JP) 2005-207979

(51) Int. Cl. G01B 7/00; G01R 31/28

(52) U.S. Cl. 33/1 PT; 324/500

(57) ABSTRACT

This invention provides an encoder including an abnormality detecting device capable of promptly and securely detecting abnormality of the encoder even when abnormality occurs in a power supply of an encoder circuit. A power supply for an encoder circuit (30) and a power supply for an abnormality detecting device (40) use power supplies different from each other, respectively. An analog signal A, which represents a signal state of each unit, for detecting an abnormal state of the encoder is input from the encoder circuit (30) to an abnormality detecting circuit (41). The abnormality detecting circuit (41) detects whether a level of the analog signal falls within a predetermined range or not. When it is detected that the level falls out of the predetermined range, an abnormal signal is generated and the signal is input to an abnormal signal transmitting circuit (42).

### TECHNICAL FIELD

The present invention relates to an encoder including an abnormality detecting circuit that detects abnormality of the encoder and an abnormal signal transmitting circuit that transmits the signal detected by the abnormality detecting circuit to the outside, and relates to an encoder including an abnormality detecting device for securely driving a control system on the basis of the abnormality signal from the encoder and a control system thereof.

### BACKGROUND ART

Conventionally, there was disclosed a position detector having abnormality informing means built in a connector to perform an abnormality informing operation in accordance with an alarm signal output from an encoder device. (e.g., see Patent Document 1)

FIG. 10 is a block diagram illustrating an electrical configuration of the encoder device described in Patent Document 1.

As shown in the figure, an encoder device 200 includes a detection unit 210, an interpolation/alarm unit 220, and a driver 230. The interpolation/alarm unit 220, to which a pseudo sine wave signal is interpolated from the detection unit 210, converts the pseudo sine wave signal into a resolution biphase square wave signal. In addition, the interpolation/alarm unit 220 has a function of detecting a scale error caused by over-speed and outputting an alarm signal AL. The driver 230 is a tri-state buffer, and the driver 230 becomes a high impedance state in accordance with the alarm signal AL.

A control device 300 is connected to the encoder device 200 through a first connector 270 provided at a position easily visible from the outside and a second connector 280 connected to the first connector 270. The first connector 270 is provided with an alarm displayer 290 between a power supply line and an alarm signal line.

Next, an operation in a case where abnormality is detected by the control device 300 will be described.

When the control device 300 detects abnormality from a difference between a position instruction and a position feedback, the control device 300 checks whether the input signal becomes high impedance or not. When the input signal is the high impedance and the alarm displayer 290 does not light, this case has been judged as cable disconnection, poor connection, or abnormality of control device 300. A case of lighting the alarm displayer 290 has been judged as fault in the encoder device 200.

As described above, in the conventional encoder device, the signal is interpolated from the detection unit to the interpolation/alarm unit provided in the encoder device, the signal is converted into the biphase square wave signal, the scale error is detected, and then the alarm signal is output.

### Patent Document 1: Japanese Patent Application Laid-Open No. 2000-193489

### DISCLOSURE OF THE INVENTION

### Problem that the Invention is to Solve

However, in the conventional encoder device, one power is supplied to the interpolation/alarm unit. That is, the signal processing unit that processes the signal interpolated from the detection unit to output the position signal and the abnormality detecting circuit that detects the error to output the alarm signal have the common power supply. Accordingly, when abnormality occurs in the power supply or abnormality occurs in the power supply line, the operation of the abnormality detecting circuit is unstable and thus it is difficult to accurately judge and process the abnormality.

The present invention has been made to solve the aforementioned problems, and an object of the invention provides an encoder including an abnormality detecting device capable of promptly and securely detecting abnormality of signals in the encoder device, even when abnormality occurs in the power supply of the circuit unit of the encoder.

### Means for Solving the Problem

In order to solve the aforementioned problems, the present invention is configured as follow.

According to a first aspect of the invention, there is provided an encoder for detecting displacement such as a rotational angle or a linear position of a detection object, the encoder comprising:

a detection unit that detects a signal in accordance with the displacement of the detection object;

an encoder circuit that processes the signal received from the detection unit and outputs a signal in accordance with the displacement; and

an abnormality detecting device that detects an abnormal state of the encoder,

wherein an electric power for the encoder circuit and an electric power for the abnormality detecting device are supplied separately.

According to a second aspect of the invention, there is provided an encoder for detecting displacement such as a rotational angle or a linear position of a detection object, the encoder comprising:

a detection unit that detects a signal in accordance with the displacement of the detection object;

an encoder circuit that processes the signal received from the detection unit and outputs a signal in accordance with the displacement;

a first wiring cable that is connected to a power supply and an output signal portion of the encoder circuit;

a second wiring cable that is connected to a power supply and an abnormal signal output portion of an abnormality detecting device; and

the abnormality detecting device that detects an abnormal state of the encoder,

wherein an electric power for the encoder circuit and an electric power for the abnormality detecting device are supplied separately, and

wherein the first wiring cable and the second wiring cable use cables different from each other.

According to a third aspect of the invention, there is provided an encoder for detecting displacement such as a rotational angle or a linear position of a detection object, the encoder comprising:

a detection unit that detects a signal in accordance with the displacement of the detection object;

an encoder circuit that processes the signal received from the detection unit and outputs a signal in accordance with the displacement; and

an abnormality detecting device that detects an abnormal state of the encoder,

wherein an electric power for the abnormality detecting device is supplied from a power supply of the encoder circuit through a circuit including a reverse current preventing diode connected to the power supply and a high-capacitance capacitor for accumulating charges obtained through the reverse current preventing diode.

According to a fourth aspect of the invention, the signal for detecting the abnormal state of the encoder may be a power supply voltage signal of the encoder circuit.

According to a fifth aspect of the invention, the signal for detecting the abnormal state of the encoder may be a waveform voltage signal detected by the angle detection unit.

According to a sixth aspect of the invention, the signal for detecting the abnormal state of the encoder may be an LED current signal corresponding to an electric current that flows through an LED of the angle detection unit.

According to a seventh aspect of the invention, the abnormality detecting device may include an environmental abnormality detecting element for detecting an environmental state of the encoder including the abnormality detecting device.

According to an eighth aspect of the invention, the environmental abnormality detecting element may be a temperature detecting element.

According to a ninth aspect of the invention, the environmental abnormality detecting element may a vibration detecting element.

According to a tenth aspect of the invention, the abnormality detecting device may have a function of transmitting a signal for informing a normal operation state when a predetermined time elapses after applying an electric power.

According to an eleventh aspect of the invention, the abnormality detecting device may have a function of sending and receiving abnormality detection signals through two-way communication.

According to a twelfth aspect of the invention, there is provided a control system comprising:

a motor that has the encoder according to any one of the first to eleventh aspects of the invention;

a control device that is connected to the encoder; and

a motor driving device that drives the motor in accordance with a control signal from the control device,

wherein the control device is operable to:
detect an abnormal signal from the encoder; and
control the motor in accordance with an abnormal state.

### ADVANTAGE OF THE INVENTION

The present invention has the following advantages.

According to the first aspect of the invention, the encoder circuit and the abnormality detecting device are separately provided, and the electric powers are supplied thereto from the different power supplies. Accordingly, when abnormality occurs in the power supply of the encoder circuit, it is possible to promptly output an abnormal signal. Therefore, it is possible to improve reliability of the encoder.

According to the second aspect of the invention, the different cables are used for the wiring cable of the abnormality detecting device and the wiring cable of the encoder circuit, respectively. Accordingly, even when abnormality occurs in the power supply voltage of the encoder circuit due to disconnection of the wiring cable of the encoder circuit, the abnormality detecting device can promptly output an abnormal signal. Therefore, it is possible to improve reliability of the encoder.

According to the third aspect of the invention, the electric power for the abnormality detecting device is supplied from the power supply of the encoder circuit through the reverse current preventing diode for preventing reverse electric current by the high-capacitance capacitor connected in parallel to the power supply of the abnormality detecting device. Accordingly, even when the power supply of the encoder circuit is cut off due to disconnection in the wiring cable of the encoder circuit, the electric power of the abnormality detecting device is backed up in the high-capacitance capacitor for a short time and meantime an abnormality detection signal is output from the abnormality detecting device. Therefore, it is possible to improve reliability of the encoder with a simple configuration.

According to the fourth aspect of the invention, the power supply voltage signal of the encoder circuit is detected. Accordingly, it is possible to promptly or previously detect poor operation of the encoder circuit on the basis of the abnormality in the power supply voltage. Therefore, it is possible to further improve reliability of the encoder.

According to the fifth aspect of the invention, the waveform voltage signal is detected. Accordingly, it is possible to promptly or previously detect poor operation of the encoder circuit on the basis of the abnormality in the waveform voltage. Therefore, it is possible to improve reliability of the encoder.

According to the sixth aspect of the invention, the electric current of the LED is detected. Accordingly, it is possible to promptly or previously detect poor operation of the encoder circuit on the basis of the abnormality in the electric current of the LED. Therefore, it is possible to improve reliability of the encoder.

According to the seventh aspect of the invention, the abnormality detecting device is provided with the environmental abnormality detecting element. Accordingly, it is possible to promptly or previously detect poor operation of the encoder circuit on the basis of the abnormality in the environmental state of the encoder. Therefore, it is possible to improve reliability of the encoder.

According to the eighth aspect of the invention, the abnormality detecting device is provided with the temperature detecting element. Accordingly, it is possible to promptly or previously detect poor operation of the encoder circuit on the basis of the abnormality in the temperature of the encoder. Therefore, it is possible to improve reliability of the encoder.

According to the ninth aspect of the invention, the abnormality detecting device is provided with the vibration detecting element. Accordingly, it is possible to promptly or previously detect poor operation of the encoder circuit on the basis of the abnormality in the vibration of the encoder. Therefore, it is possible to improve reliability of the encoder.

According to the tenth aspect of the invention, the abnormality detecting device has the function of transmitting the signal for informing a normal operation state when a predetermined time elapses after applying an electric power. Accordingly, it is possible to verify a normal operation of the abnormality detecting device. Therefore, it is possible to improve reliability of the abnormality detecting device, thereby improving reliability of the encoder.

According to the eleventh aspect of the invention, the abnormality detecting device has the function of sending and receiving abnormality detection signals through two-way communication. Accordingly, it is possible to continuously verify a normal operation of the abnormality detecting device. Therefore, it is possible to improve reliability of the encoder.

According to the twelfth aspect of the invention, the control system detects the abnormality signal of the encoder including the abnormality detecting device, determines how the control device copes with the abnormal state, and performs the process such as the prompt stop of the motor. Therefore, it is possible to construct a control system with safety and high reliability.

### BRIEF DESCRIPTION OF THE DRAWINGS

FIG. 1 is a block diagram illustrating a first embodiment of the present invention;

FIG. 2A is a perspective view illustrating a configuration of an angle detection unit, and FIG. 2B is a circuit diagram illustrating an encoder circuit;

FIG. 3 is a block diagram illustrating a second embodiment of the present invention;

FIG. 4 is a block diagram illustrating a third embodiment of the present invention;

FIG. 5 is a block diagram illustrating a fourth embodiment of the present invention;

FIG. 6 is a time chart illustrating an operation of the fourth embodiment;

FIG. 7 is a block diagram illustrating a fifth embodiment of the present invention;

FIG. 8 is a time chart illustrating an operation of the fifth embodiment;

FIG. 9 is a block diagram illustrating a sixth embodiment of the present invention; and

FIG. 10 is a block diagram illustrating a configuration of a conventional example.

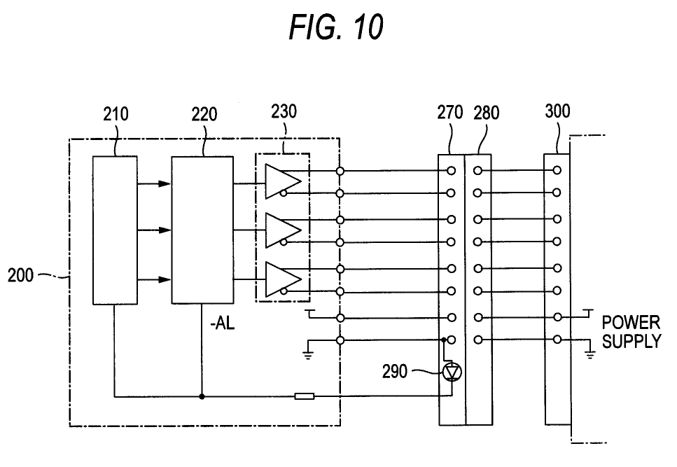

### DESCRIPTION OF REFERENCE NUMERALS AND SIGNS

10: ENCODER INCLUDING ABNORMALITY DETECTING DEVICE
20: ANGLE DETECTION UNIT
21: LED
22: FIXED SLIT
23: PHOTODIODE
24: HUB
25: ROTATIVE DISK
30: ENCODER CIRCUIT
31: OPERATIONAL AMPLIFIER
32: COMPARATOR
33: RESISTOR
34: OUTPUT SIGNAL PORTION
40: ABNORMALITY DETECTING DEVICE
41: ABNORMALITY DETECTING CIRCUIT
42: ABNORMAL SIGNAL TRANSMITTING CIRCUIT
43: ABNORMAL SIGNAL OUTPUT PORTION
51: REVERSE CURRENT PREVENTING DIODE
52: HIGH-CAPACITANCE CAPACITOR
60: ENVIRONMENTAL ABNORMALITY DETECTING ELEMENT
61: TEMPERATURE DETECTING ELEMENT
62: VIBRATION DETECTING ELEMENT
71: NORMAL SIGNAL GENERATING CIRCUIT
72: TWO-WAY ABNORMAL SIGNAL GENERATING CIRCUIT
81: FIRST WIRING CABLE
82: SECOND WIRING CABLE
83: WIRING CABLE
90: CONTROL DEVICE
91: RECEPTION ABNORMAL SIGNAL DETECTING CIRCUIT UNIT
92: RECEPTION CONTROL CIRCUIT
93: ABNORMAL SIGNAL
94: ABNORMAL SIGNAL OUTPUT
100: MOTOR DRIVING DEVICE
110: MOTOR
200: ENCODER DEVICE
210: DETECTION UNIT
220: INTERPOLATION/ALARM UNIT
230: DRIVER
270: FIRST CONNECTOR
280: SECOND CONNECTOR
290: ALARM DISPLAYER
300: CONTROL DEVICE
711: POWER SUPPLY VOLTAGE
712: OUTPUT SIGNAL OF NORMAL SIGNAL GENERATING CIRCUIT
721: SIGNAL WAVEFORM OF ABNORMAL SIGNAL OUTPUT PORTION
722: ABNORMALITY INQUIRY SIGNAL
723: SIGNAL REPRESENTING NORMAL OPERATION

### BEST MODE FOR CARRYING OUT THE INVENTION

Hereinafter, embodiments of the invention will be described with reference to the drawings.

### Embodiment 1

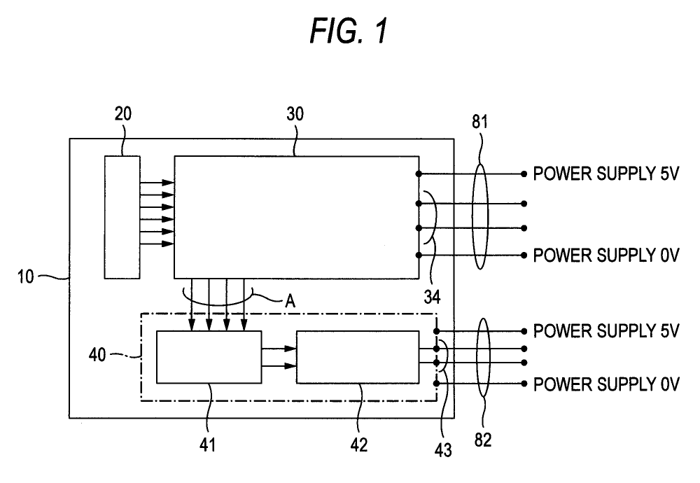

FIG. 1 is a block diagram illustrating a first embodiment of the present invention. In the figure, reference numeral 10 denotes an encoder including an abnormality detecting device, and the encoder 10 includes an angle detection unit 20 that detects displacement of a rotational angle, an encoder circuit 30 that shapes a waveform of a detection signal to output a signal in accordance with the displacement, and an abnormality detecting device 40 placed on a separate board having a power supply line different from a power supply line for a board of the encoder circuit 30. The abnormality detecting device 40 includes an abnormality detecting circuit 41 and an abnormality transmitting circuit 42.

Reference numeral 81 denotes a first wiring cable including wires for supplying an electric power to the encoder circuit 30 and wires of an output signal portion 34 of the encoder circuit 30. Reference numeral 82 denotes a second wiring cable including wires for supplying an electric power to the abnormality detecting device 40 and wires of the abnormal signal output portion 43. The first wiring cable 81 and the second wiring cable 82 use cables difference from each other.

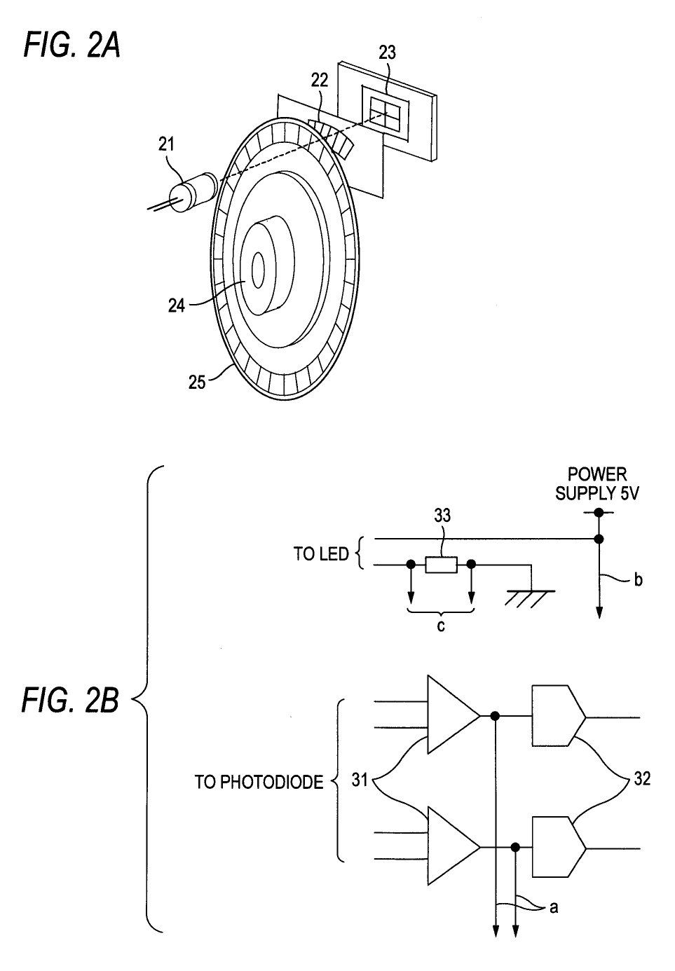

FIG. 2A is a perspective view illustrating a configuration of the angle detection unit 20 according to the embodiment.

The angle detection unit 20 includes an LED 21, a fixed slit 22, and a photodiode 23. The angle detection unit 20 detects a rotational angle of a detection object (not shown) by the use of a rotative disk 25 fixed to a hub 24, the fixed slit 22, and the photodiode 23, and then the angle detection unit 20 transmits an electric signal corresponding to the rotational angle to the encoder circuit 30.

Next, an operation of the embodiment will be described.

In FIG. 1, an analog signal A representing a signal state of each unit of the encoder to detect an abnormality state of the encoder is input from the encoder circuit 30 to the abnormality detecting circuit 41. The abnormality detecting circuit 41 detects whether a level of the analog signal A falls within a predetermined range or not. When the abnormality detecting circuit 41 detects that the level falls out of the predetermined range, the abnormality detecting circuit 41 generates an abnormal signal and inputs the abnormal signal to the abnormal signal transmitting circuit 42.

Next, a specific example of the analog signal A will be described.

FIG. 2B is a circuit diagram illustrating a part of the encoder circuit 30 according to the embodiment.

In the figure, reference numeral 31 denotes an operational amplifier that amplifies the signal detected by the photodiode 23. Reference numeral 32 denotes a comparator that converts the amplified signal into a rectangular wave. An output of the operational amplifier 31 is a waveform voltage signal and is input to the abnormality detecting circuit 41. Reference numeral 33 denotes a resistor for detecting an electric current of the LED. A voltage between both ends of the resistor 33 is an LED current signal and is input to the abnormality detecting circuit 41.

As specific examples of the analog signal A representing an encoder state, the following a), b), and c) may be used.

a) A power supply voltage signal that represents a power supply voltage of the encoder circuit 30

b) A waveform voltage signal that represents a voltage of a signal waveform according to displacement of a detection object (not shown) that is inputted from the angle detection unit 20 to the encoder circuit 30

In the embodiment, a maximum value and a minimum value of a signal waveform having a pseudo sine waveform output from the angle detection unit are detected.

c) An LED current signal that represents an electric current of the LED 23

In the embodiment as describe above, even when an abnormality occurs in the power supply voltage signal due to disconnection of a cable, and even when an abnormality occurs in the waveform voltage signal or the LED current signal due to fault of an element, the abnormality of the encoder circuit is securely detected and the abnormal signal is transmitted from the abnormal signal detecting device because the board and the wire of the abnormality detecting device are different from those of encoder circuit, thereby improving reliability.

Since the analog signal is detected, it is possible to set the abnormality detection level according to a situation. Since the detection level is allowed to have a margin, it is possible to safely stop a system before malfunction occurs in the system employing the encoder

In the present invention, the board of the encoder circuit 30 and the board of the abnormality detecting device 40 are described as the boards different from each other. However, even when the circuits are separately formed on the same board to simplify constituent parts, the same advantage is attained.

In the embodiment, there is described the example of the circuit amplifying the output of the photodiode and converting the output into the rectangular waveform by the comparator in the encoder circuit, but a circuit that outputs an analog signal obtained by amplifying the output of the photodiode may be used.

### Embodiment 2

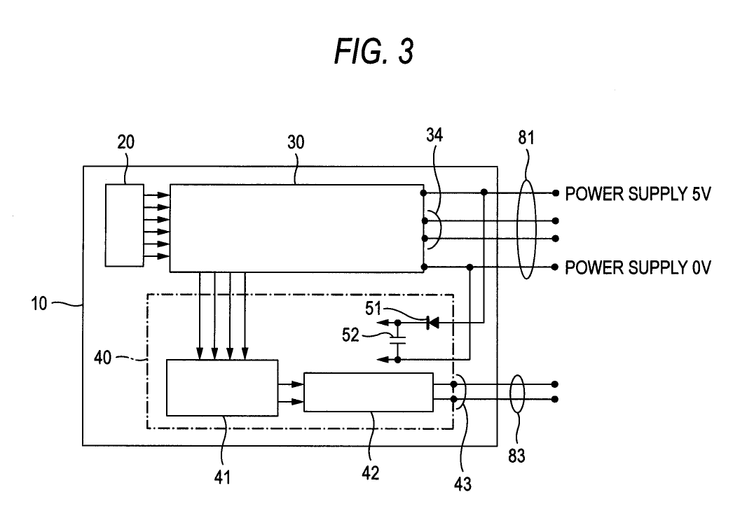

FIG. 3 is a block diagram illustrating a second embodiment of the present invention. In the figure, reference numeral 51 denotes a reverse current preventing diode, and reference numeral 52 denotes a high-capacitance capacitor. Reference numeral 83 denotes a wiring cable composed of the wires of the abnormal signal output portion 43, and the wiring cable 83 has no wire for the power supply of the abnormality detecting device 40.

The embodiment is different from the first embodiment as follow. In the first embodiment, the power supply of the encoder circuit 30 and the power supply of the abnormality detecting device 40 employ separate power supplies different from each other, but in the embodiment, the power supply of the encoder circuit 30 and the power supply of the abnormality detecting device 40 are commonly integrated to supply electric power from the power supply of the encoder circuit 30 to the abnormality detecting device 40 by the reverse current preventing diode 51 and the high-capacitance capacitor 52.

Next, an operation of the embodiment will be described.

When the power supply wires of the encoder circuit 30 are in the supply-impossible state due to disconnection or the like, electric power is temporarily supplied to the abnormality detecting device 40 by capacitance of the high-capacitance capacitor 52. In the course of supplying the electric power, the abnormality detecting device 40 detects abnormality in power supply of the encoder circuit 30 and outputs an abnormal signal.

In the embodiment, since the power supply of the encoder circuit and the power supply of the abnormality detecting device are commonly integrated, the number of wires from the power supply decreases and thus chance of disconnection decreases. In addition, since one power supply may be used, the configuration is simplified.

### Embodiment 3

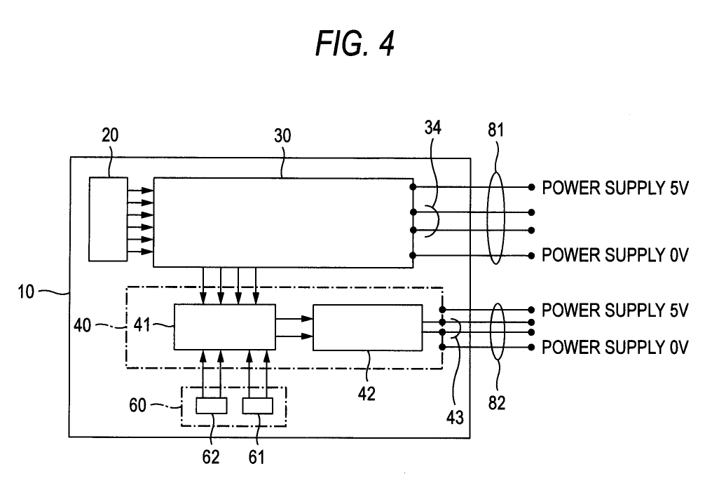

FIG. 4 is a block diagram illustrating a third embodiment of the present invention. In the figure, reference numeral 60 denotes an environmental abnormality detecting element.

The embodiment is different from the first embodiment in that the encoder 10 including the abnormality detecting device has the environmental abnormality detecting element 60.

In the embodiment, as the environmental abnormality detecting element 60, there are provided a temperature detecting element 61 for detecting temperature of the encoder and a vibration detecting element 62 for detecting vibration of the encoder. A thermistor is used as the temperature detecting element 61, and an acceleration sensor is used as the vibration detecting element 62.

Next, an operation of the embodiment will be described.

The temperature detecting element 61 detects temperature of the encoder 10, and an analog signal corresponding to the temperature is sent to the abnormality detecting circuit 41. Similarly, the vibration detecting element 62 detects vibration of the encoder 10, and an analog signal corresponding to the vibration is sent to the abnormality detecting circuit 41. When the temperature or the vibration of the encoder is more than a predetermined range, abnormal signals are generated. These abnormal signals are output from the abnormal signal transmitting circuit 42.

In the embodiment as described above, since the encoder including the abnormality detecting device is provided with the vibration detecting element, it is possible to prevent problems of electric components or mechanic components and poor circuit operation caused by environmental abnormality such as increase in temperature or vibration of the encoder. Accordingly, it is possible to further improve reliability of the encoder.

### Embodiment 4

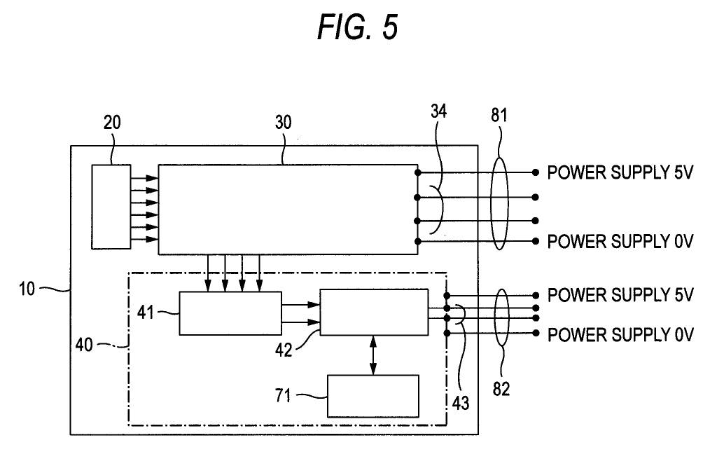

FIG. 5 is a block diagram illustrating a fourth embodiment of the present invention. In the figure, reference numeral 71 denotes a normal signal generating circuit.

The embodiment is different from the first embodiment in that the abnormality detecting device 40 is provided with the normal signal generating circuit 71 for informing a normal operation state of the encoder 10 including the abnormality detecting device when a predetermined time elapses after applying an electric power.

Next, an operation of the embodiment will be described.

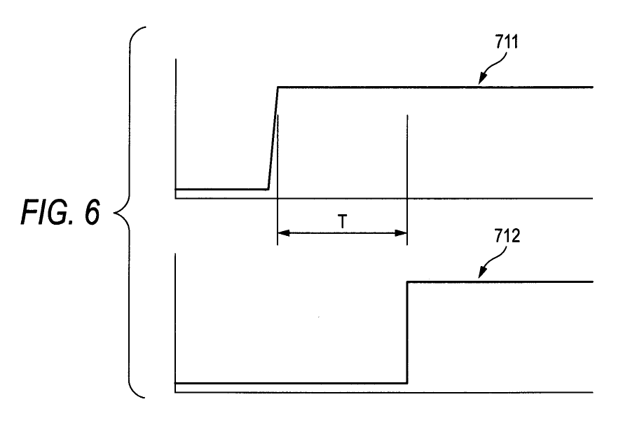

FIG. 6 is a time chart illustrating an operation of the embodiment.

In the figure, reference numeral 711 denotes a power supply voltage of the abnormality detecting device 40, and reference numeral 712 denotes an output signal of the abnormal signal generating circuit.

When an electric power is applied to the abnormality detecting device 40, the normal signal generating circuit 71 detects that the abnormality detecting device 40 normally operates, and then the normal signal generating circuit 71 outputs a signal that becomes a high level after T seconds set by the normal signal generating circuit 71 from the time of applying the electric power. When the signal becomes the high level immediately upon applying the electric power, a high level signal caused by breakdown of the abnormality detecting device 40 may be output. Accordingly, there is provided a function of outputting the signal representing a normal operation state from the abnormality detecting device 40 after a predetermined time such as the T seconds, thereby improving reliability in detection.

In the embodiment as described above, since the abnormality detecting device is provided with the normal signal generating circuit and it is detected whether the abnormality detecting device normally operates at the time of applying the electric power or not, it is possible to improve reliability of the abnormality detecting device and to further improve reliability of the encoder.

### Embodiment 5

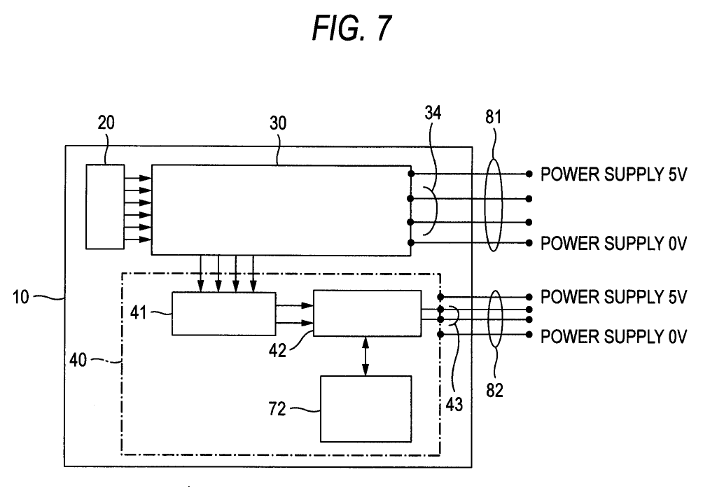

FIG. 7 is a block diagram illustrating a fifth embodiment of the present invention. In the figure, reference numeral 72 a two-way abnormal signal generating circuit for checking an operation of the abnormality detecting device 40 through two-way communication with a control device (not shown).

The embodiment is different from the fourth embodiment as follow. In the fourth embodiment, the abnormality detecting device 40 is provided with the normal signal generating circuit 71, but in the embodiment, the abnormality detecting device 40 is provided with the two-way abnormal signal generating circuit 72 and checks the operation of the abnormality detecting device through the two-way communication.

Next, an operation of the embodiment will be described.

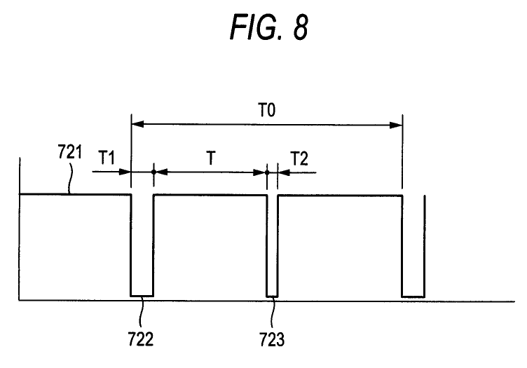

FIG. 8 is a time chart illustrating an operation of the embodiment.

In the figure, reference numeral 721 denotes a signal waveform of the abnormal signal output portion.

An abnormality inquiry signal 722 that shorts an output end of the abnormal signal transmitting circuit 42 for a short time (T1) at a predetermined time period (T0) is output from a control device (not shown). The two-way abnormal signal generating circuit 72 outputs a low-level signal 723 representing a normal operation for a short time (T2) after T seconds when the short is released.

A control circuit (not shown) receives the signal, thereby sensing a normal operation of the abnormality detecting device 40. For example, in case of T0=0.1 seconds, T1=0.01 seconds, T=0.05 seconds and T2=0.005 seconds, it is possible to monitor the normal state at a high speed of 0.1 seconds.

In the embodiment, the operation in the manner of shorting the output end of the abnormal signal transmitting circuit 42 for the short time is described. However, although the aforementioned manner is not used, there may be provided a circuit capable of sending and receiving communication signals such as “inquiry of abnormality” and “response of normal operation”.

In the embodiment as described above, the abnormality detecting device is provided with the two-way abnormal signal generating circuit and the operation of the abnormality detecting device is continuously checked. Accordingly, it is possible to further improve reliability of the encoder.

### Embodiment 6

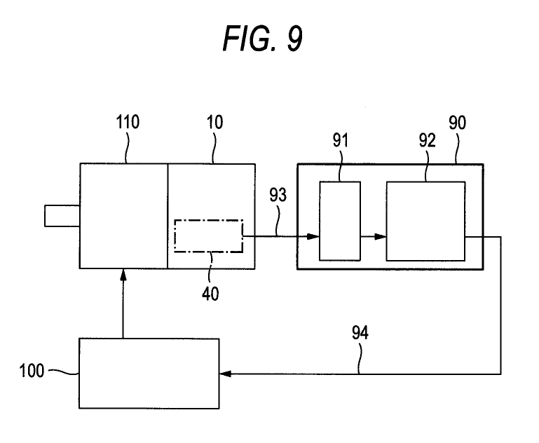

FIG. 9 is a block diagram illustrating a sixth embodiment of the present invention.

In the figure, reference numeral 90 denotes a control device, reference numeral 100 denotes a motor driving device, and reference numeral 110 denotes a motor that is applied to an industrial machine such as a machine tool (not shown) and is provided with the encoder 10 including the abnormality detecting device of the present invention. The control device 90 includes a reception abnormal signal detecting circuit unit 91 and a reception control circuit 92.

Next, an operation of the embodiment will be described.

When an abnormal signal 93 is sent from the encoder 10 including the abnormality detecting device to the reception abnormal signal detecting circuit unit 91, the reception control circuit 92 determines how to cope with the situation, for example, prompt stop or emergency stop of the motor 110. Then, the reception control circuit 92 sends an abnormal signal output 94 to the motor driving device 100.

In the embodiment as described above, on the basis of the abnormal signal output generated by the reception control circuit of the control device, the control device determines how to cope with the situation, and the control device outputs the result thereof as the abnormal signal output and performs the process such as the prompt stop of the motor. Accordingly, it is possible to construct a control system with safety and high reliability.

### INDUSTRIAL APPLICABILITY

The present invention is applicable to an encoder for detecting a rotational position or a linear displacement of a motor used in various industrial machineries such as semiconductor manufacturing devices, robots, and NC machine tools.

As the embodiments, the rotation-type optical encoder is described, but the invention is not limited to any one of a rotational type and a linear type. In addition, the present invention is not limited to any one of an optical type and a magnetic type.

1. An encoder for detecting displacement of a detection object, the encoder comprising:
a detection unit that detects a signal in accordance with the displacement of the detection object;
an encoder circuit that processes the signal received from the detection unit and outputs a signal in accordance with the displacement; and
an abnormality detecting device that detects an abnormal state of the encoder,
wherein an electric power for the encoder circuit and an electric power for the abnormality detecting device are supplied separately.

2. An encoder for detecting displacement of a detection object, the encoder comprising:
a detection unit that detects a signal in accordance with the displacement of the detection object;
an encoder circuit that processes the signal received from the detection unit and outputs a signal in accordance with the displacement;
an abnormality detecting device that detects an abnormal state of the encoder,
a first wiring cable that is connected to a power supply and an output signal portion of the encoder circuit;
a second wiring cable that is connected to a power supply and an abnormal signal output portion of an abnormality detecting device; and
wherein an electric power for the encoder circuit and an electric power for the abnormality detecting device are supplied separately, and
wherein the first wiring cable and the second wiring cable use cables different from each other.

3. An encoder for detecting displacement of a detection object, the encoder comprising:
a detection unit that detects a signal in accordance with the displacement of the detection object;
an encoder circuit that processes the signal received from the detection unit and outputs a signal in accordance with the displacement; and
an abnormality detecting device that detects an abnormal state of the encoder,
wherein an electric power for the abnormality detecting device is supplied from a power supply of the encoder circuit through a circuit including a reverse current preventing diode connected to the power supply and a high-capacitance capacitor for accumulating charges obtained through the reverse current preventing diode.

4. The encoder according to any one of claims 1 to 3, wherein the signal for detecting the abnormal state of the encoder is a power supply voltage signal of the encoder circuit.

5. The encoder according to any one of claims 1 to 3, wherein the signal for detecting the abnormal state of the encoder is a waveform voltage signal detected by the detection unit.

6. The encoder according to any one of claims 1 to 3, wherein the signal for detecting the abnormal state of the encoder is an LED current signal corresponding to an electric current that flows through an LED of the detection unit.

7. The encoder according to any one of claims 1 to 3, wherein the abnormality detecting device includes an environmental abnormality detecting element for detecting an environmental state of the encoder including the abnormality detecting device.

8. The encoder according to claim 7, wherein the environmental abnormality detecting element is a temperature detecting element.

9. The encoder according to claim 7, wherein the environmental abnormality detecting element is a vibration detecting element.

10. The encoder according to any one of claims 1 to 3, wherein the abnormality detecting device has a function of transmitting a signal for informing a normal operation state when a predetermined time elapses after applying an electric power.

11. The encoder according to any one of claims 1 to 3, wherein the abnormality detecting device has a function of sending and receiving abnormality detection signals through two-way communication.

12. A control system comprising:
a motor that has the encoder according to any one of claims 1 to 3;
a control device that is connected to the encoder; and
a motor driving device that drives the motor in accordance with a control signal from the control device,
wherein the control device is operable to:
detect an abnormal signal from the encoder; and
control the motor in accordance with an abnormal state.
